(19) United States
(12) Patent Application Publication
(10) Pub. No.: US 2023/0327057 A1
(43) Pub. Date: Oct. 12, 2023

(54) DISPLAY DEVICE

(71) Applicant: Samsung Display Co., LTD., Yongin-si (KR)

(72) Inventors: Jeongsoo KIM, Asan-si (KR); Suk Hoon KANG, Seoul (KR); Beom-Soo SHIN, Seongnam-si (KR); Sung Hwan HONG, Suwon-si (KR)

(73) Assignee: Samsung Display Co., LTD., Yongin-si (KR)

(21) Appl. No.: 18/112,708

(22) Filed: Feb. 22, 2023

(30) Foreign Application Priority Data
Apr. 6, 2022 (KR) 10-2022-0042927

(51) Int. Cl. H01L 33/50; H01L 33/38

(52) U.S. Cl. CPC H01L 33/505; H01L 33/382

(57) ABSTRACT

An embodiment of the disclosure provides a display device including a color converting panel and a display panel disposed to overlap the color converting panel in a first direction. The display panel includes a first substrate, a plurality of first banks disposed on the first substrate, and a light emitting area disposed between adjacent ones of the plurality of first banks. The color converting panel includes a second substrate, a plurality of second banks disposed on the second substrate, and a color converting layer and a transmissive layer, each disposed between adjacent ones of the plurality of second banks. The plurality of second banks includes a scatterer, each of the plurality of second banks and the light emitting area overlap in the first direction, and the first direction is perpendicular to the first substrate.

### CROSS-REFERENCE TO RELATED APPLICATION(S)

This application claims priority to and benefits of Korean Patent Application No. 10-2022-0042927 under 35 U.S.C. § 119, filed on Apr. 6, 2022, in the Korean Intellectual Property Office (KIPO), the entire contents of which are incorporated herein by reference.

### BACKGROUND

### 1. Technical Field

The disclosure relates to a display device that may increase light efficiency.

### 2. Description of the Related Art

A light-emitting device is a device in which holes supplied from an anode and electrons supplied from a cathode are combined in a light emitting layer formed between the anode and the cathode to form excitons, and light is emitted while the excitons are stabilized.

The light-emitting device has several merits such as a wide viewing angle, a fast response speed, a thin thickness, and lower power consumption such that the light-emitting device is widely applied to various electrical and electronic devices such as a television, a monitor, a mobile phone, and the like.

Recently, in order to realize a high-efficiency display device, a display device including a color converting panel has been proposed. The color converting panel converts incident light into different colors. In this case, the incident light is mainly blue light, and the blue light is converted to red light and green light, respectively, or transmitted as blue light itself.

The above information disclosed in this Background section is only for enhancement of understanding of the background of the disclosure, and therefore it may contain information that does not form the prior art that is already known in this country to a person of ordinary skill in the art.

### SUMMARY

Embodiments provide a display device that may maximize light efficiency.

An embodiment provides a display device that may include: a color converting panel; and a display panel disposed to overlap the color converting panel in a first direction. The display panel may include: a first substrate; first banks disposed on the first substrate; and a light emitting area disposed between adjacent ones of the first banks. The color converting panel may include: a second substrate; second banks disposed on the second substrate; and a color converting layer and a transmissive layer, each disposed between adjacent ones of the second banks. The second banks may include a scatterer, each of the second banks and the light emitting area may overlap in the first direction, and the first direction may be perpendicular to the first substrate.

The scatterer may include one or more of SiO₂, BaSO₄, Al₂O₃, ZnO, ZrO₂, and TiO₂.

A content of the scatterer may be in a range of about 0.1 wt % to about 20 wt %.

A length of an area in which each of the second banks and the light emitting area overlap may be in a range of about 0.01% to about 40% of a length of each of the second banks in a second direction.

Each of the second banks may further include a non-overlapping area that does not overlap the light emitting area in the first direction, and a length of the non-overlapping area in a second direction may be greater than or equal to about 10 μm.

An absorbance of the second banks with respect to light of a wavelength of 450 nm may be greater than or equal to about 0.9.

A transmittance of the second banks with respect to straight light of a wavelength of 450 nm may be less than or equal to about 1%.

A length in a second direction of an area in which the second banks and the light emitting area overlap may be in a range of about 0.1 μm to about 15 μm.

The first banks and the second banks may each overlap in the first direction.

A length of each of the first banks in a second direction may be shorter than a length of each of the second banks in the second direction.

The first banks may absorb light.

The second banks may scatter incident light.

The light emitting area may include: a first electrode; a light-emitting device layer disposed on the first electrode; and a second electrode disposed on the light-emitting device layer.

The light-emitting device layer may emit blue light.

The color converting layer may include a red color converting layer and a green color converting layer. The red color converting layer, the green color converting layer, and the transmissive layer may be each disposed between adjacent ones of the second banks.

The display device may further include: a red color filter disposed between the red color converting layer and the second substrate; a green color filter disposed between the green color converting layer and the second substrate; and a blue color filter disposed between the transmissive layer and the second substrate.

The display device may further include a light blocking member disposed between the red color filter, the green color filter, and the blue color filter.

The display panel may further include a non-light-emitting area, a blue light-emitting area, a red light-emitting area, and a green light-emitting area. The blue color filter may be disposed in the blue light-emitting area and the non-light-emitting area, and the blue color filter disposed in the non-light-emitting area may form a blue dummy color filter.

The red color filter may be disposed in the red light-emitting area and the non-light-emitting area, and the red color filter disposed in the non-light-emitting area may form a red dummy color filter.

The green color filter may be disposed in the green light-emitting area and the non-light-emitting area, and the green color filter disposed in the non-light-emitting area may form a green dummy color filter.

The blue dummy color filter, the red dummy color filter, and the green dummy color filter may overlap in the first direction in the non-light-emitting area.

The blue dummy color filter may be disposed closer to the second substrate than the red dummy color filter or the green dummy color filter.

The display device may further include a low refractive layer disposed on the red color filter, the green color filter, and the blue color filter. A refractive index of the low refractive layer may be less than or equal to about 1.2.

The display device may further include a first insulating layer disposed on the low refractive layer. A refractive index of the first insulating layer may be in a range of about 1.4 to about 1.6.

The first insulating layer may include silicon oxide.

The display device may further include a buffer layer disposed between the display panel and the color converting panel. A refractive index of the buffer layer may be in a range of about 1.6 to about 1.7.

The display device may further include a second insulating layer disposed between the color converting layer and the buffer layer, and between the transmissive layer and the buffer layer. A refractive index of the second insulating layer may be in a range of about 1.4 to about 1.6.

The second insulating layer may include SiON.

According to the embodiments, a display device that maximizes light efficiency is provided.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view illustrating a display device according to an embodiment.

FIG. 2 illustrates a line light source, and FIG. 3 illustrates luminance measurement of the line light source in a cross-section taken along line III-III′ of FIG. 2.

FIG. 4 illustrates a surface light source, and FIG. 5 illustrates luminance measurement of the surface light source in a cross-section taken along line V-V′ of FIG. 4.

FIG. 6 to FIG. 9 respectively illustrate a scattering amount while varying a distance between a second bank and a light source.

FIG. 10 is a schematic cross-sectional view illustrating an overlapping relationship between a second bank and a light emitting area.

FIG. 11 is a schematic cross-sectional view illustrating a display device in which a separation distance between a second bank and a light emitting area is 7.5 μm, and FIG. 12 is a schematic cross-sectional view illustrating a display device in which an overlapping distance between a second bank and a light emitting are 7.5 μm.

FIG. 13 is a graph illustrating measurement of light efficiency according to a separation distance between a light emitting area LA and a second bank 320 with respect to a second bank including a scatterer and a black bank.

FIG. 14 is a schematic cross-sectional view of a display device according to another embodiment.

FIG. 15 to FIG. 17 illustrate top plan views of a stacking process of a color filter in FIG. 14.

### DETAILED DESCRIPTION OF THE EMBODIMENTS

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

In order to clearly describe the disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YA, and ZZ. As used herein, the term “and/or” includes any and all combinations of one or more of the associated listed items.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

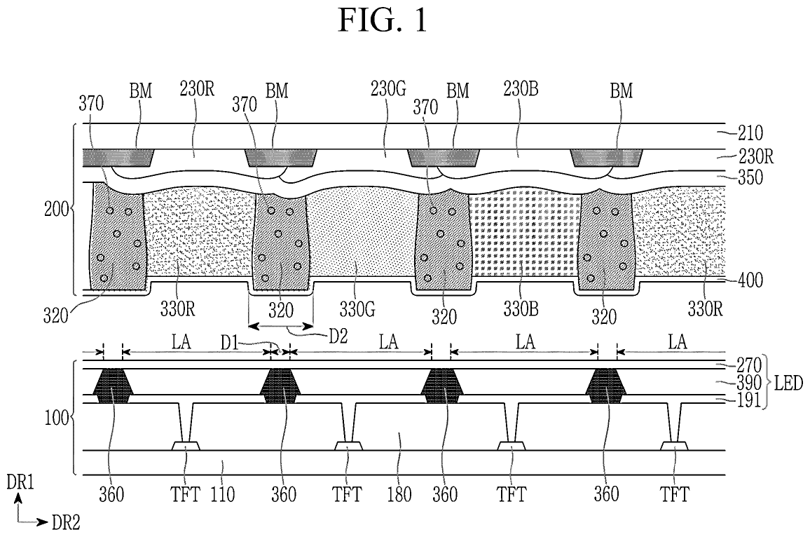

FIG. 1 illustrates a display device according to an embodiment. The display device according to the embodiment may include a display panel 100 and a color converting panel 200.

The display panel 100 may include a first substrate 110, and multiple transistors TFT and an insulating film 180 positioned on the first substrate 110. A first electrode 191 and a first bank 360 may be positioned in the insulating film 180, and the first electrode 191 may be positioned at an opening of the first bank 360 and electrically connected to the transistor TFT. Although not specifically illustrated, the transistor TFT may include a semiconductor layer, a source electrode and a drain electrode electrically connected to the semiconductor layer, and a gate electrode insulated from the semiconductor layer. A second electrode 270 may be positioned on the first bank 360, and a light-emitting device layer 390 may be positioned between the first electrode 191 and the second electrode 270. The first electrode 191, the second electrode 270, and the light-emitting device layer 390 may be collectively referred to as a light-emitting device LED. Multiple light-emitting devices LED may emit light of different colors or may emit light of the same color. For example, the light-emitting device LED may emit light of red, green, or blue, respectively. In another embodiment, all of the light-emitting devices LED may emit blue light.

The first bank 360 may include a black material to prevent color mixing between adjacent light-emitting devices LED. A light emitting area LA in the display panel 100 may be an area between adjacent first banks 360. The light emitting area LA is shown in FIG. 1. The light emitting area LA may be an area in which light is actually emitted from the display panel 100.

The color converting panel 200 may include a second substrate 210 and a light blocking member BM positioned on the second substrate 210. The light blocking members BM may be spaced apart from each other with a space therebetween. A first color filter 230R, a second color filter 230G, and a third color filter 230B may be positioned in respective areas between the light blocking members BM spaced apart from each other.

The first color filter 230R may be a red color filter, the second color filter 230G may be a green color filter, and the third color filter 230B may be a blue color filter. However, the disclosure is not limited thereto.

A planarization layer 350 may be positioned on the first color filter 230R, the second color filter 230G, and the third color filter 230B. The planarization layer 350 may planarize a surface of the color filter 230 while preventing the color filter 230 from directly contacting the color converting layer and the transmissive layer.

A second bank 320 may be positioned on the planarization layer 350. The second banks 320 may be positioned to be spaced apart from each other with an opening therebetween, and each opening may overlap each of the color filters 230R, 230G, and 230B in a direction perpendicular to the surface of the first substrate 110.

A red color converting layer 330R, a green color converting layer 330G, and a transmissive layer 330B may be positioned in an area between the second banks 320 spaced apart from each other. For example, as shown in FIG. 1, the red color converting layer 330R, the green color converting layer 330G, and the transmissive layer 330B may be positioned in respective spaces partitioned by the second bank 320. A second insulating layer 400 may be positioned on the red color converting layer 330R, the green color converting layer 330G, and the transmissive layer 330B.

The red color converting layer 330R may convert supplied blue light into red light. The green color converting layer 330G may convert supplied blue light into green light. The red color converting layer 330R and the green color converting layer 330G may include quantum dots.

Hereinafter, the quantum dot will be described in detail.

In the specification, the quantum dot (hereinafter also referred to as a semiconductor nanocrystal) may include a group II-VI compound, a group III-V compound, a group IV-VI compound, a group IV element or compound, a group compound, a group compound, a group I-II-IV-VI compound, or a combination thereof.

The group II-VI compound may be selected from the group consisting of: a binary element compound selected from CdSe, CdTe, ZnS, ZnSe, ZnTe, ZnO, HgS, HgSe, HgTe, MgSe, MgS, and a mixture thereof; a ternary element compound selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The group II-VI compound may further include a group III metal.

The group III-V compound may be selected from the group consisting of: a binary element compound selected from GaN, GaP, GaAs, GaSb, AlN, AlP, AlAs, AlSb, InN, InP, InAs, InSb, and a mixture thereof; a ternary element compound selected from GaNP, GaNAs, GaNSb, GaPAs, GaPSb, AlNP, AINAs, AlNSb, AlPAs, AlPSb, InGaP, InNP, InNAs, InNSb, InPAs, InZnP, InPSb, and a mixture thereof; and a quaternary element compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The group III-V compound may further include a group II metal (for example, InZnP).

The group IV-VI compound may be selected from the group consisting of: a binary element compound selected from SnS, SnSe, SnTe, PbS, PbSe, PbTe, and a mixture thereof; a ternary element compound selected from SnSeS, SnSeTe, SnSTe, PbSeS, PbSeTe, PbSTe, SnPbS, SnPbSe, SnPbTe, and a mixture thereof; and a quaternary element compound selected from SnPbSSe, SnPbSeTe, SnPbSTe, and a mixture thereof.

The group IV element or compound may be selected from the group consisting of a singular element compound selected from Si, Ge, and a combination thereof, and a binary element compound selected from SiC, SiGe, and a combination thereof, but is not limited thereto.

The group compound may include, for example, CuInSe₂, CuInS₂, CuInGaSe, and CuInGaS, but is not limited thereto. The group I-II-IV-VI compound may include, for example, CuZnSnSe and CuZnSnS, but is not limited thereto. The group IV element or compound may be selected from the group consisting of a singular element selected from Si, Ge, and a mixture thereof, and a binary element compound selected from SiC, SiGe, and a mixture thereof.

The group compound may be selected from the group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and a combination thereof, but is not limited thereto.

The group I-II-IV-VI compound may be selected from the group consisting of CuZnSnSe and CuZnSnS, but is not limited thereto.

In the embodiment, the quantum dot may not include cadmium. The quantum dot may include a semiconductor nanocrystal based on a group III-V compound including indium and phosphorus. The group III-V compound may further include zinc. The quantum dot may include a semiconductor nanocrystal based on a group II-VI compound including a chalcogen element (for example, sulfur, selenium, tellurium, or a combination thereof) and zinc.

In the quantum dot, the binary element compound, the ternary element compound, and/or the quaternary element compound, which are described above, may be present in particles at uniform concentrations, or they may be divided into states having partially different concentrations to be present in the same particle, respectively. A core/shell structure in which some quantum dots enclose some other quantum dots may be possible. An interface between the core and the shell may have a concentration gradient in which a concentration of elements of the shell decreases closer to its center.

In embodiments, the quantum dot may have a core-shell structure that includes a core including the nanocrystal described above and a shell surrounding the core. The shell of the quantum dot may serve as a passivation layer for maintaining a semiconductor characteristic and/or as a charging layer for applying an electrophoretic characteristic to the quantum dot by preventing chemical denaturation of the core. The shell may be a single layer or a multilayer. An interface between the core and the shell may have a concentration gradient in which a concentration of elements of the shell decreases closer to its center. The shell of the quantum dot may include a metal or nonmetal oxide, a semiconductor compound, or a combination thereof.

For example, the metal or non-metal oxide may be a binary element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like, or a ternary element compound such as MgAl₂O₄, CoFe₂O₄, NiFe₂O₄, CoMn₂O₄, and the like, but the disclosure is not limited thereto.

The semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the disclosure is not limited thereto.

An interface between the core and the shell may have a concentration gradient in which a concentration of elements of the shell decreases closer to its center. The semiconductor nanocrystal may have a structure including one semiconductor nanocrystal core and a multi-layered shell surrounding the semiconductor nanocrystal core. In the embodiment, the multi-layered shell may have two or more layers, for example, two, three, four, five, or more layers. Two adjacent layers of the shell may have a single composition or different compositions. In the multi-layered shell, each layer may have a composition that varies along a radius.

The quantum dot may have a full width at half maximum (FWHM) of a light-emitting wavelength spectrum that is equal to or less than about 45 nm. For example, the quantum dot may have a FWHM of a light-emitting wavelength spectrum that is equal to or less than about 40 nm. For example, the quantum dot may have a FWHM of a light-emitting wavelength spectrum that is equal to or less than about 30 nm. In these ranges, color purity or color reproducibility may be improved. Light emitted through a quantum dot may be emitted in all directions, so that a viewing angle of light may be improved.

In the quantum dot, the shell material and the core material may have different energy bandgaps. For example, the energy bandgap of the shell material may be greater than that of the core material. In another embodiment, the energy bandgap of the shell material may be smaller than that of the core material. The quantum dot may have a multi-layered shell. In the multi-layered shell, an energy bandgap of an outer layer thereof may be larger than that of an inner layer thereof (for example, a layer closer to the core). In the multi-layered shell, the energy bandgap of the outer layer may be smaller than the energy bandgap of the inner layer.

The quantum dot may adjust an absorption/emission wavelength by adjusting a composition and size thereof. The maximum emission peak wavelength the quantum dot absorbs or emits may have a wavelength range from ultraviolet to infrared wavelengths or more.

The quantum dot may have a quantum efficiency of about 10% or more, for example, about 30% or more, about 50% or more, about 60% or more, about 70% or more, about 90% or more, or even 100%. The quantum dot may have a relatively narrow spectrum. The quantum dot may have a full width of half maximum of an emission wavelength spectrum of, for example, about 50 nm or less, for example, about 45 nm or less, about 40 nm or less, or about 30 nm or less.

The quantum dot may have a particle size of about 1 nm or more and about 100 nm or less. The particle size may be a particle diameter or a diameter converted by assuming a spherical shape from a 2-dimensional image obtained by transmission electron microscope analysis. The quantum dot may have a size of about 1 nm to about 20 nm, for example, 2 nm or more, 3 nm or more, or 4 nm or more and 50 nm or less, 40 nm or less, 30 nm or less, 20 nm or less, 15 nm or less, or 10 nm or less. A shape of the quantum dot is not particularly limited. For example, the shape of the quantum dot may have a sphere, a polyhedron, a pyramid, a multi-pod, a square, a cuboid, a nanotube, a nanorod, a nanowire, a nanosheet, or a combination thereof, but is not limited thereto.

The quantum dots are commercially available, or may be appropriately synthesized. In case that the quantum dot is colloid-synthesized, the particle size may be relatively freely controlled, and may also be uniformly controlled.

The quantum dot may include an organic ligand (for example, having a hydrophobic moiety and/or a hydrophilic moiety). The organic ligand moiety may be bound to a surface of the quantum dot. The organic ligand may include RCOOH, RNH₂, R₂NH, R₃N, RSH, R₃PO, R₃P, ROH, RCOOR, RPO(OH)₂, RHPOOH, R₂POOH, or a combination thereof, wherein R may be a C₃ to C₄₀ substituted or unsubstituted aliphatic hydrocarbon group such as a C₃ to C₄₀ (for example, C₅ or greater and C₂₄ or less) substituted or unsubstituted alkyl, or a substituted or unsubstituted alkenyl, a C₆ to C₄₀ (for example, C₆ or greater and C₂₀ or less) substituted or unsubstituted aromatic hydrocarbon group such as a substituted or unsubstituted C₆ to C₄₀ aryl group, or a combination thereof.

The organic ligand may be: a thiol compound such as methane thiol, ethane thiol, propane thiol, butane thiol, pentane thiol, hexane thiol, octane thiol, dodecane thiol, hexadecane thiol, octadecane thiol, or benzyl thiol; an amine such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, or trioctylamine; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, or benzoic acid; a phosphine compound such as methyl phosphine, ethyl phosphine, propyl phosphine, butyl phosphine, pentyl phosphine, octylphosphine, dioctyl phosphine, tributylphosphine, or trioctylphosphine; a phosphine compound or an oxide compound thereof such as methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, or trioctylphosphine oxide; a diphenyl phosphine, a triphenyl phosphine compound, or an oxide compound thereof; a C5 to C20 alkyl phosphonic acid such as hexylphosphinic acid, octylphosphinic acid, dodecanephosphinic acid, tetradecanephosphinic acid, hexadecanephosphinic acid, octadecanephosphinic acid; and the like, but are not limited thereto. The quantum dot may include a hydrophobic organic ligand alone or a mixture of at least one type. The hydrophobic organic ligand may not include a photopolymerizable moiety (for example, an acrylate group, a methacrylate group, etc.).

In the embodiment, the second bank 320 may include a scatterer 370. The scatterer 370 may be one or more of SiO₂, BaSO₄, Al₂O₃, ZnO, ZrO₂, and TiO₂. The second bank 320 may include a polymer resin and a scatterer included in the polymer resin.

A content of the scatterer 370 in the second bank 320 may be about 0.1 wt % to about 20 wt %. In another embodiment, the content of the scatterer 370 in the second bank 320 may be about 5 wt % to about 10 wt %. The second bank 320 including the scatterers 370 within the above-described range may scatter light emitted from the light-emitting device layer 390 to increase light efficiency.

For example, in the display device according to the embodiment, the second bank 320 may scatter light without blocking it. Accordingly, the light emitted from the light-emitting device LED may be scattered in the second bank 320, and thus the light efficiency of the display device may be increased.

Straight light transmittance (UV-vis) at a wavelength of 450 nm of the second bank 320 may be about 1% or less. Absorbance for light at a wavelength of 450 nm of the second bank 320 may be about 0.9 or more. Accordingly, the second bank 320 may prevent color mixing between adjacent color converting layers. Specific light characteristics of the second bank 320 will be separately described later.

The light emitting area LA of the display device may overlap the second bank 320 in a direction perpendicular to the first substrate 110. Since the second bank 320 and the light emitting area LA are positioned to overlap in this way, scattering of the display device may be increased and light emitting efficiency may be increased.

For example, as shown in FIG. 1, a width D1 of the first bank 360 in a second direction DR2 of the display panel 100 may be narrower than a width D2 of the second bank 320 in the second direction DR2. A portion of the second bank 320 does not overlap the first bank 360 in a first direction DR1 perpendicular to the first substrate 110. As described above, since a portion of the light emitting area LA is positioned to overlap the second bank 320 in the direction perpendicular to the first substrate 110, the scattering may increase and the light emitting efficiency may be improved.

Hereinafter, an effect of improving the light emitting efficiency in the case in which the second bank 320 and the light emitting area LA overlap will be described.

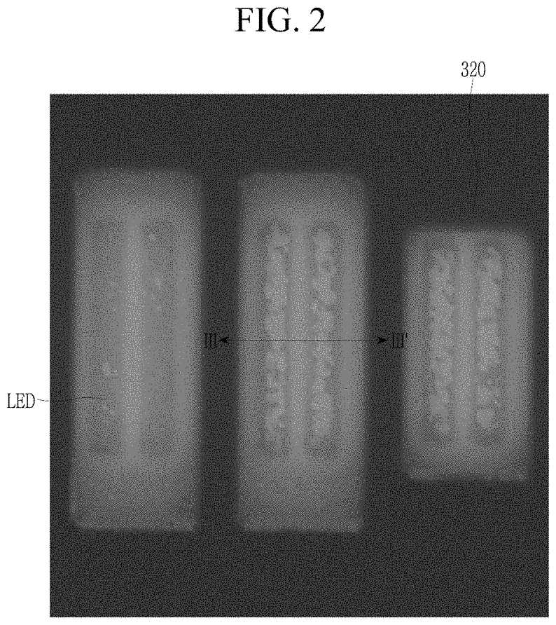

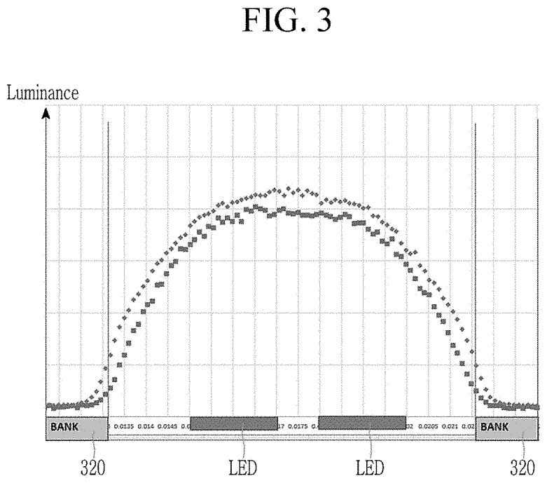

The luminance for each position is measured for a line light source shown in FIG. 2, and the result is shown in FIG. 3. FIG. 3 illustrates measurement of luminance of the line light source in a cross-section taken along line III-III′ of FIG. 2. In FIG. 2, an area between light sources LED is the second bank 320.

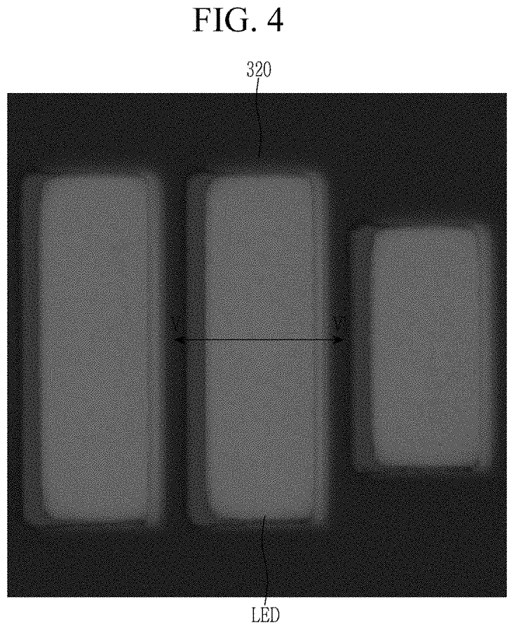

The luminance for each position is measured for a surface light source shown in FIG. 4, and the result is shown in FIG. 5. FIG. 5 illustrates measurement of luminance of the surface light source in a cross-section taken along line V-V′ of FIG. 4. In FIG. 5, an area between light sources LED is the second bank 320.

Comparing FIG. 3 and FIG. 5, the distance between the second bank 320 and the light source LED is shorter in FIG. 5 than in FIG. 3. It can be confirmed that the brightness is higher in FIG. 5 than in FIG. 3.

This is because loss occurs in the process of light movement as the distance between the second bank 320 and the light source LED increases.

For the line light source shown in FIG. 2, the luminance was measured while varying the material of the second bank, and for the surface light source shown in FIG. 4, the luminance was measured while varying the material of the second bank, and the measured results are shown in Table 1.

TABLE 1

| | Bank | | Improved efficiency |
|---|---|---|---|
| Light source | material | Luminance | compared to black bank |
| Surface light | Black | 483025.1 | — |
| source | TiO₂ 6% | 570975.7 | 18% increase |
| | TiO₂ 8% | 584986.1 | 21% increase |
| Line light | Black | 366502.6 | — |
| source | TiO₂ 6% | 411084.3 | 12% increase |
| | TiO₂ 8% | 415933.8 | 13% increase |

As shown in Table 1, it can be seen that in case that the second bank 320 includes TiO₂ as a scatterer, compared to where the second bank 320 includes a black material, the efficiency thereof is improved. Hereinafter, an effect of improving the efficiency of the second bank 320 including the scatterer will be described.

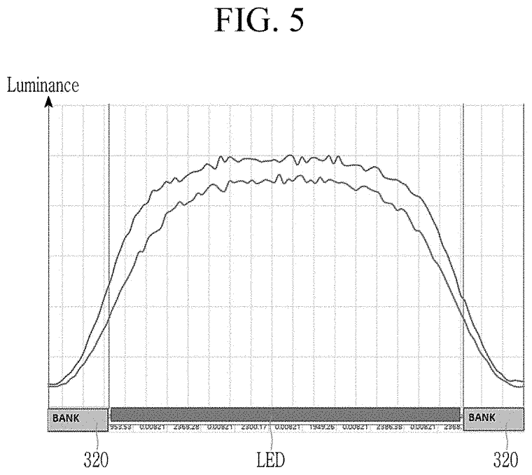

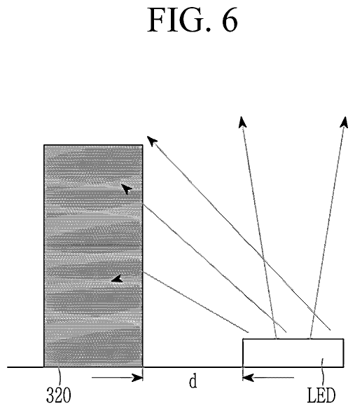

FIG. 6 to FIG. 9 respectively illustrate a scattering amount while varying a distance between the second bank 320 and the light source LED. In FIG. 6 to FIG. 9, for better comprehension and ease of description, the shapes of the second bank 320 and the light source LED are briefly illustrated, and they may be different from the actual shapes thereof.

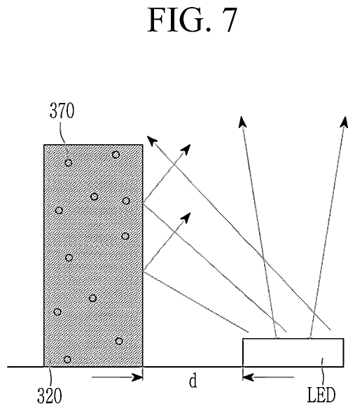

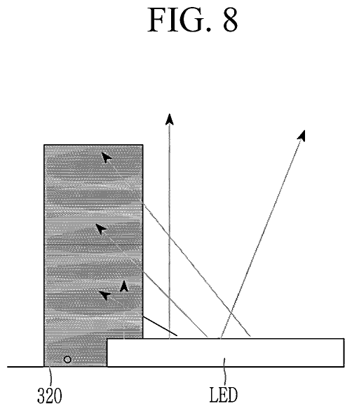

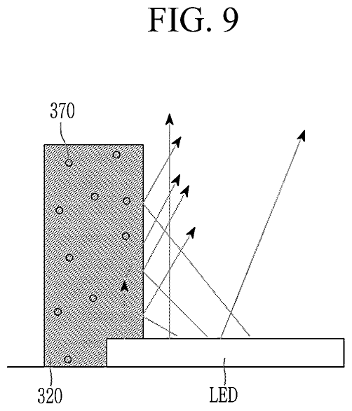

The second bank 320 in FIG. 6 and FIG. 8 includes the black material to block light, and the second bank 320 in FIG. 7 and FIG. 9 includes the scatterer 370 to scatter light. In FIG. 6 and FIG. 7, the second bank 320 and the light source LED are spaced apart from each other by a distance (d), and in FIG. 8 and FIG. 9, the second bank 320 and the light source LED are positioned to overlap (or partially overlap).

Comparing FIG. 6 and FIG. 8 with FIG. 7 and FIG. 9, in FIG. 6 and FIG. 8 in which the second bank 320 includes the black material, light incident on the second bank 320 is not reflected but absorbed. However, in the case of FIG. 7 and FIG. 9, the light incident to the second bank 320 is scattered by the scatterers 370 in the second bank 320 to be emitted out of the second bank 320. Accordingly, it is possible to increase the luminous efficiency.

Comparing FIG. 7 and FIG. 9, in the case of FIG. 7 in which the second bank 320 and the light source LED are spaced apart from each other, light scattered by the second bank 320 is limited. For example, an amount of the light incident to the second bank 320 is a portion of the entire light, and most of the light is not scattered by the second bank 320 but is emitted.

However, referring to FIG. 9, in case that the second bank 320 and the light source LED overlap, most of light emitted from the light source LED is scattered by the second bank 320. Accordingly, compared to the case of FIG. 7, the amount of scattered light may be large, and the light efficiency may be increased.

As shown in FIG. 1, in the display device according to the embodiment, the light emitting area LA and the second bank 320 may overlap, and the second bank 320 may include the scatterer 370. Accordingly, it is possible to increase the light efficiency of the display device.

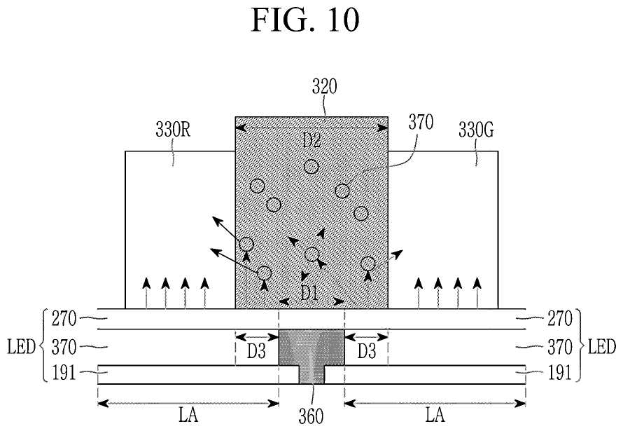

FIG. 10 schematically illustrates the overlapping relationship between the second bank 320 and the light emitting area LA. In FIG. 10, for better comprehension and ease of description, constituent elements are simply illustrated, and the shapes of those illustrated may be different from the actual specific shapes. Referring to FIG. 10, the width D1 of the second bank 320 that does not overlap the light emitting area LA may be about 10 μm or more. This may be a minimum range in which the light emitted from the adjacent light emitting areas LA overlapping the second bank 320 is not mixed.

For example, in case that the entire width D2 of the second bank 320 is 40 μm, an overlapping distance D3 of the second bank 320 and the light emitting area LA may be about 0.1 μm to about 15 μm. This is the same for areas of both sides of the second bank 320. The width D1 of the second bank 320 not overlapping the light emitting area LA may be 10 μm, so that color mixing of light emitted from both light emitting areas LA may be prevented.

In the embodiment, the overlapping width D3 of the second bank 320 and the light emitting area LA may be about 0.01% to about 40% of the entire width D2 of the second bank 320. For example, in case that the entire width D2 of the second bank 320 is increased, the overlapping width D3 of the second bank 320 and the light emitting area LA may also be increased. However, the width D1 of the second bank 320 that does not overlap the light emitting area LA must be about 10 μm or more.

In case that the overlapping width D3 of the second bank 320 and the light emitting area LA is less than 0.01% of the entire width D2 of the second bank 320, sufficient scattering may not be realized. In case that the overlapping width D3 of the second bank 320 and the light emitting area LA is more than 40% of the entire width D2 of the second bank 320, the light emitted from both light emitting areas LA may be mixed.

In order to prevent color mixing, absorbance (OD) of the second bank 320 may be about 0.9 or more.

Table 2 shows the results of measuring the absorbance (OD), luminance, and color coordinates while setting the width of the second bank 320 that does not overlap the light emitting area LA to 10 μm and varying the materials of the second bank 320.

TABLE 2

| | | | | | | Color |
|---|---|---|---|---|---|---|
| Pigment | | | | | | reproduc- |
| concentration | OD | Color | Lumi. | Color x | Color y | tivity |
| Black | 1.7 | RED | 2.65 | 0.7051 | 0.2943 | 92.20% |
| | | GREEN | 12.58 | 0.1976 | 0.7527 | |
| | | BLUE | 0.02 | 0.1752 | 0.3714 | |
| TiO₂ | 1.4 | RED | 1.85 | 0.704 | 0.2953 | 92.00% |
| 0.75% | | GREEN | 11.6 | 0.1983 | 0.7513 | |
| | | BLUE | 0.02 | 0.1761 | 0.3702 | |
| TiO₂ | 0.9 | RED | 1.64 | 0.704 | 0.2952 | 91.80% |
| 0.10% | | GREEN | 13.49 | 0.1993 | 0.7488 | |
| | | BLUE | 0.02 | 0.1762 | 0.3713 | |

Referring to the Table 2, it can be confirmed that the absorbance of the second bank 320 also decreases as the content of the scatterer (TiO₂) decreases. It can be confirmed that the difference in color reproducibility is 0.5% or less in case that the second bank 320 having an absorbance of 0.9 is compared with the black bank having an absorbance of 1.7. The color reproducibility was measured with the C.I.E 1976 color coordinate system. Accordingly, as long as the absorbance of the second bank 320 is 0.9 or more, it can be confirmed that color mixing is prevented and the color reproducibility similar to that of the embodiment including the black bank is obtained. Table 3 below shows the results of measuring transmittance and absorbance of light at 450 nm while varying the thicknesses for the second bank including 6% of the scatterer TiO₂ and the black bank. UV-vis, which uses straight light, and CM-3600D, which uses light in the form of an integrating sphere, were used as measuring instruments.

TABLE 3

| | Bank thickness | | | | | | | |
|---|---|---|---|---|---|---|---|---|
| | 10 μm | | 12 μm | | 15 μm | | | |
| | Spectrometer | | | | | | | |
| | CM-3600D | | UV-vis | | CM-3600D | UV-vis | CM-3600D | UV-vis |
| Measurement | Transmittance | Absorbance | Transmittance | Absorbance | Absorbance | | Absorbance | |
| Scattering | 13.12% | 0.9 | 0.99% | 2 | 1.1 | 2.4 | 1.4 | 3 |
| bank | | | | | | | | |
| (TiO₂ 6%) | | | | | | | | |
| C-Bank | 8.54% | 1.1 | 2.96% | 1.5 | 1.3 | 1.8 | 1.7 | 2.3 |
| (Black) | | | | | | | | |

Referring to Table 3, in the second bank including TiO₂ of 6%, it can be confirmed that the absorbance is 0.9 in case that the second bank has the thickness of 10 μm. The absorbance showed a tendency to increase as the thickness of the second bank increased. Table 4 shows the results of measuring color coordinates, luminance, and color reproducibility for the second bank including the scatterer and the black bank.

The results of Table 4 show the color coordinates and luminance of each of red, green, and blue light passing through the color converting layer, the transmissive layer, and the color filter in the display device in which the light source emits blue light.

TABLE 4

| | Black bank | | | Scattering bank | | |
|---|---|---|---|---|---|---|
| | Blue | Green | Red | Blue | Green | Red |
| X | 0.1415 | 0.1936 | 0.7029 | 0.1420 | 0.1952 | 0.7029 |
| Y | 0.0392 | 0.7290 | 0.2922 | 0.0383 | 0.7243 | 0.2919 |
| Lumi. | 23.2 | 27.2 | 16.7 | 38.1 | 39.6 | 25.9 |
| | | | | 164% | 146% | 155% |

| | | |
|---|---|---|
| Color | 92.8% | 92.4% |
| reproducibility | | |

As shown in Table 4, it was confirmed that the luminance of each of RGB colors was increased in the display device including the second bank including a scatterer. It was confirmed that the color reproducibility was 92.4%, which was similar to the color reproducibility of 92.8% of the display device including the black bank. The color reproducibility was measured with the BT2020 color coordinate system. Table 5 shows the results of measuring color coordinates and color reproducibility for the black bank and the second bank including 6% of TiO₂ as a scatterer.

TABLE 5

| | | Color | Color | Color | |
|---|---|---|---|---|---|
| | | coordinate | coordinate | repro- | |
| | Color | (x) | (y) | ducibility | Remarks |
| Black bank | RED | 0.703 | 0.295 | 87.3% | No color |
| | GREEN | 0.208 | 0.744 | | coordinate |
| | BLUE | 0.147 | 0.016 | | change |
| Scattering bank | RED | 0.703 | 0.296 | 87.1% | |
| (TiO₂ 6%) | GREEN | 0.206 | 0.743 | | |
| | BLUE | 0.148 | 0.015 | | |

Referring to Table 5, even in the case of the second bank including the scatterer, it was confirmed that it has substantially the same color coordinates as the black bank and it has substantially the same color reproducibility as the black bank.

As described above, in the second bank including the scatterer according to the embodiment, it can be confirmed that the color coordinates and color reproducibility are not affected in case that the absorbance of the second bank 320 is 0.9 or more.

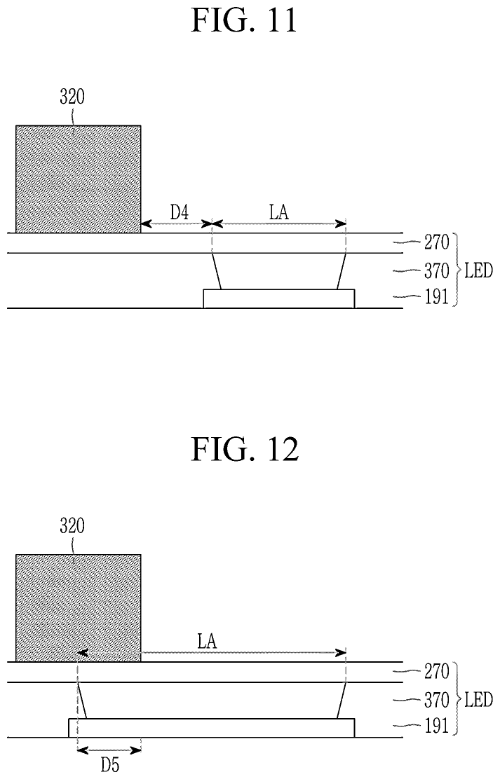

FIG. 11 schematically illustrates the display device in which a separation distance D4 between the second bank 320 and the light emitting area LA is 7.5 μm, and FIG. 12 schematically illustrates the display device in which an overlapping distance (D5) between the second bank 320 and the light emitting area LA is 7.5 μm. Table 6 shows the results of measuring the luminance while varying the material of the second bank with respect to the embodiments of FIG. 11 and FIG. 12.

TABLE 6

| | | | Efficiency |
|---|---|---|---|
| | Black | Scattering | compared to |
| Evaluation sample | Bank | bank TiO₂ | Black Bank |
| FIG. 11 (Separation distance | 483025 | 570975 | 12.2%↑ |
| 7.5 μm) | | | |
| FIG. 12 (Overlapping distance | 495697.5 | 555995.1 | 18.2%↑ |
| 7.5 μm) | | | |

Referring to Table 6, as shown in FIG. 11, in the display device in which the separation distance between the second bank 320 and the light emitting area LA is 7.5 μm, it was confirmed that the scattering efficiency of the second bank including the scatterer was increased by 12.2% compared to the black bank. As shown in FIG. 12, in the display device in which the overlapping distance between the second bank 320 and the light emitting area LA is 7.5 μm, it was confirmed that the scattering efficiency of the second bank including the scatterer was increased by 18.2% compared to the black bank.

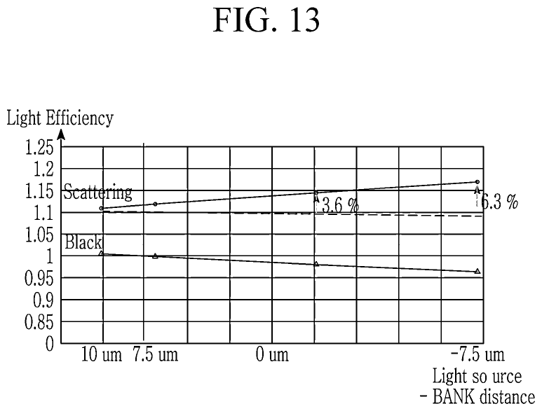

FIG. 13 illustrates measurement of light efficiency according to the separation distance between the light emitting area LA and the second bank 320 with respect to the second bank including the scatterer and the black bank. In the case of the separation distance of 7.5 μm from the black bank, the efficiency is set to 1, and the relative values are shown.

Referring to FIG. 13, it can be confirmed that the efficiency of the second bank including the scatterer increased as the separation distance decreased and as the overlapping distance increased compared to the black bank.

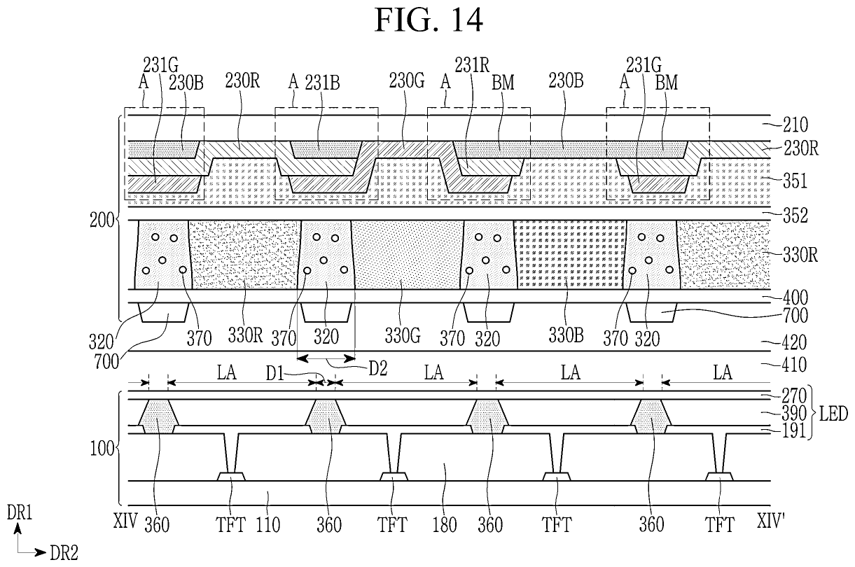

FIG. 14 illustrates a schematic cross-sectional view of a display device according to another embodiment. Referring to FIG. 14, in the display device according to the embodiment, the shape of the color filter 230 of the color converting panel 200 is different from that of FIG. 1.

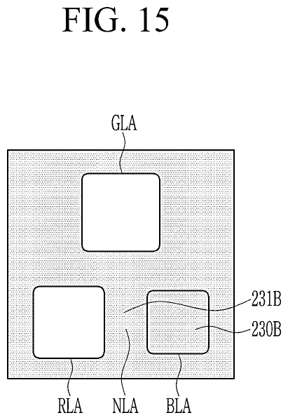

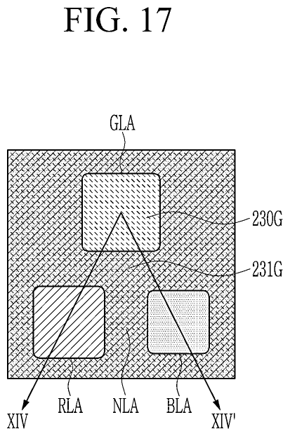

FIG. 15 to FIG. 17 illustrate top plan views of a stacking process of the color filter 230 in FIG. 14. FIG. 14 illustrates a cross-sectional view taken along line XIV-XIV′ of FIG. 17. Hereinafter, it will be described in detail with reference to FIG. 14 to FIG. 17.

As shown in FIG. 14, the display device according to the embodiment may include the blue color filter 230B positioned on the second substrate 210. A blue dummy color filter 231B may be positioned on the same layer as the blue color filter 230B. In FIG. 14, although the blue color filter 230B and the blue dummy color filter 231B are illustrated as being separated from each other, this is only a structure viewed in a cross-sectional view, and referring to FIG. 15, the blue color filter 230B and the blue dummy color filter 231B may be connected to each other.

FIG. 15 illustrates a top plan view in which the blue color filter 230B and the blue dummy color filter 231B are formed. Referring to FIG. 15, the blue color filter may be formed on the entire substrate except a green light emitting area GLA and a red light emitting area RLA, and a color filter of a blue color positioned in a blue light emitting area BLA may form the blue color filter 230B, while a color filter of a blue color positioned in a non-light emitting area NLA may form the blue dummy color filter 231B. The color filter of the blue color may be not positioned in a green light emitting area GLA or a red light emitting area RLA. Referring to the cross-sectional view of FIG. 14, an edge of the blue color filter 230B and the blue dummy color filter 231B positioned in the non-light emitting area may be integral with each other.

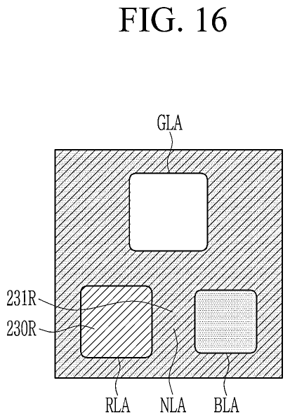

Referring to FIG. 14 and FIG. 16, the red color filter 230R and the red dummy color filter 231R may be positioned on the blue color filter 230B and the blue dummy color filter 231B. FIG. 16 illustrates a top plan view in which the red color filter 230R and the red dummy color filter 231R are formed.

Referring to FIG. 14 and FIG. 16, a color filter of a red color may be formed on the color filter of the blue color except the green light emitting area GLA and the blue light emitting area BLA. The color filter of the red color positioned in the red light emitting area RLA may form the red color filter 230R, and the color filter of the red color positioned in the non-light emitting area NLA may form the red dummy color filter 231R. The color filter of the red color may be not formed in the green light emitting area GLA or the blue light emitting area BLA.

Referring to the cross-sectional view of FIG. 14, an edge of the red color filter 230R and the red dummy color filter 231R positioned in the non-light emitting area may be integral with each other.

Referring to FIG. 14 and FIG. 17, the green color filter 230G and the green dummy color filter 231G may be positioned on the blue color filter 230B and the blue dummy color filter 231B and on the red color filter 230R and the red dummy color filter 231R. FIG. 17 illustrates a top plan view in which the green color filter 230G and the green dummy color filter 231G are formed.

Referring to FIG. 14 and FIG. 17, a color filter of a green color may be formed on the color filter of the blue color and the color filter of the red color except the red light emitting area RLA and the blue light emitting area BLA. The color filter of the green color positioned in the green light emitting area GLA may form the green color filter 230G, and the color filter of the green color positioned in the non-light emitting area NLA may form the green dummy color filter 231G. The color filter of the green color may be not formed in the red light emitting area RLA and the blue light emitting area BLA.

Referring to the cross-sectional view of FIG. 14, an edge of the green color filter 230G and the green dummy color filter 231G positioned in the non-light emitting area may be integral with each other.

In FIG. 14 to FIG. 17, the structure in which the blue color filter 230B and the blue dummy color filter 231B are formed on the second substrate 210, the red color filter 230R and the red dummy color filter 231R are formed, and the green color filter 230G and the green dummy color filter 231G are formed, is illustrated, but the stacked order of the red color filter 230R and the green color filter 230G may be changed according to embodiments.

For example, a structure in which the blue color filter 230B and the blue dummy color filter 231B are formed on the second substrate 210, the green color filter 230G and the green dummy color filter 231G are formed, and the red color filter 230R and the red dummy color filter 231R are formed, is also possible.

Referring to FIG. 14, the blue dummy color filter 231B, the red dummy color filter 231R, and the green dummy color filter 231G may overlap to form a color filter overlapping body (A). The color filter overlapping body (A) may function in the same way as the light blocking member BM of FIG. 1. For example, the color filter overlapping body (A) may prevent color mixing between adjacent light-emitting elements. The embodiment of FIG. 14 is different from the embodiment FIG. 1 in that the color filter overlapping body (A) is positioned instead of the light blocking member BM.

In the embodiment of FIG. 14, the blue dummy color filter 231B may be positioned closer to the second substrate 210 than the red dummy color filter 231R and the green dummy color filter 231G. A direction in which a user views an image is toward the second substrate 210, and the blue dummy color filter 231B may be positioned on a surface on which the image is viewed. This is because, compared with green or red, blue has lowest reflectance for entire light and may most effectively block light.

Referring to FIG. 14, a low refractive layer 351 may be positioned below the color filter 230. The low refractive layer 351 may have a refractive index of about 1.2 or less. The low refractive layer 351 may be made of a mixture of an organic material and an inorganic material.

Referring to FIG. 14, a first insulating layer 352 may be positioned on the low refractive layer 351. The first insulating layer 352 may include a SiOx. A thickness of the first insulating layer 352 may be about 3,500 Å to about 4,500 Å. A refractive index of the first insulating layer 352 may be about 1.4 to about 1.6. The first insulating layer 352 may include an inorganic material. The first insulating layer 352 may separate the low refractive layer 351, the red color converting layer 330R, the green color converting layer 330G, and the transmissive layer 330B.

The second bank 320 may be positioned on the first insulating layer 352. The second banks 320 may be positioned to be spaced apart from each other with an opening therebetween, and each opening may overlap each of the color filters 230R, 230G, and 230B in a direction perpendicular to the surface of the first substrate 110. The second bank 320 may include the scatterer 370. A description of the second bank 320 is the same as in FIG. 1, and thus will be omitted.

The red color converting layer 330R, the green color converting layer 330G, and the transmissive layer 330B may be positioned in an area between the second banks 320 spaced apart from each other. Descriptions of the red color converting layer 330R, the green color converting layer 330G, and the transmissive layer 330B are the same as in FIG. 1, and thus will be omitted.

A second insulating layer 400 may be positioned on the red color converting layer 330R, the green color converting layer 330G, and the transmissive layer 330B.

The second insulating layer 400 may cap the red color converting layer 330R, the green color converting layer 330G, and the transmissive layer 330B. The second insulating layer 400 may include a SiON. A thickness of the second insulating layer 400 may be about 3,500 Å to about 4,500 Å. A refractive index of the second insulating layer 400 may be about 1.4 to about 1.6. The second insulating layer 400 may include an inorganic material.

A column spacer 700 may be positioned on the second insulating layer 400. The column spacer 700 may be positioned to overlap the second bank 320.

In FIG. 14, an encapsulation layer 410 may be positioned on the light-emitting device LED of the display panel 100. The encapsulation layer 410 may have a multi-layered structure in which an organic layer and an inorganic layer are alternately stacked each other. Among the multi-layered encapsulation layers 410, a layer positioned farthest from the first substrate 110 may include a SiON.

A buffer layer 420 may be positioned between the encapsulation layer 410 and the second insulating layer 400. The buffer layer 420 may connect the display panel 100 and the color converting panel 200. The buffer layer 420 may include an organic material. A refractive index of the buffer layer 420 may be about 1.6 to about 1.7. The refractive index may be in a most excellent refractive index range in extraction efficiency of light emitted from the display panel 100.

As described above, in the display device according to the embodiment, the second bank positioned between the color converting layer and the transmissive layer may include the scatterer, and the light emitting area of the display panel and the second bank overlap. Accordingly, it is possible to increase the scattering of light emitted from the light emitting area and to increase the efficiency of the display device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A display device comprising:
a color converting panel; and
a display panel disposed to overlap the color converting panel in a first direction, wherein
the display panel includes:
a first substrate;
a plurality of first banks disposed on the first substrate; and
a light emitting area disposed between adjacent ones of the plurality of first banks,
the color converting panel includes:
a second substrate;
a plurality of second banks disposed on the second substrate; and
a color converting layer and a transmissive layer, each disposed between adjacent ones of the plurality of second banks,
the plurality of second banks includes a scatterer,
each of the plurality of second banks and the light emitting area overlap in the first direction, and
the first direction is perpendicular to the first substrate.

2. The display device of claim 1, wherein the scatterer includes one or more of SiO₂, BaSO₄, Al₂O₃, ZnO, ZrO₂, and TiO₂.

3. The display device of claim 1, wherein a content of the scatterer is in a range of about 0.1 wt % to about 20 wt %.

4. The display device of claim 1, wherein a length of an area in which each of the plurality of second banks and the light emitting area overlap is in a range of about 0.01% to about 40% of a length of each of the plurality of second banks in a second direction.

5. The display device of claim 1, wherein
each of the plurality of second banks further includes a non-overlapping area that does not overlap the light emitting area in the first direction, and
a length of the non-overlapping area in a second direction is greater than or equal to about 10 μm.

6. The display device of claim 1, wherein an absorbance of the plurality of second banks with respect to light of a wavelength of 450 nm is greater than or equal to about 0.9.

7. The display device of claim 1, wherein a transmittance of the plurality of second banks with respect to straight light of a wavelength of 450 nm is less than or equal to about 1%.

8. The display device of claim 1, wherein a length in a second direction of an area in which the plurality of second banks and the light emitting area overlap is in a range of about 0.1 μm to about 15 μm.

9. The display device of claim 1, wherein the plurality of first banks and the plurality of second banks each overlap in the first direction.

10. The display device of claim 1, wherein a length of each of the plurality of first banks in a second direction is shorter than a length of each of the plurality of second banks in the second direction.

11. The display device of claim 1, wherein the plurality of first banks absorb light.

12. The display device of claim 1, wherein the plurality of second banks scatter incident light.

13. The display device of claim 1, wherein the light emitting area includes:
a first electrode;
a light-emitting device layer disposed on the first electrode; and
a second electrode disposed on the light-emitting device layer.

14. The display device of claim 13, wherein the light-emitting device layer emits blue light.

15. The display device of claim 1, wherein
the color converting layer includes a red color converting layer and a green color converting layer, and
the red color converting layer, the green color converting layer, and the transmissive layer are each disposed between adjacent ones of the plurality of second banks.

16. The display device of claim 15, further comprising:
a red color filter disposed between the red color converting layer and the second substrate;
a green color filter disposed between the green color converting layer and the second substrate; and
a blue color filter disposed between the transmissive layer and the second substrate.

17. The display device of claim 16, further comprising:
a light blocking member disposed between the red color filter, the green color filter, and the blue color filter.

18. The display device of claim 16, wherein
the display panel further includes a non-light-emitting area, a blue light-emitting area, a red light-emitting area, and a green light-emitting area,
the blue color filter is disposed in the blue light-emitting area and the non-light-emitting area, and
the blue color filter disposed in the non-light-emitting area forms a blue dummy color filter.

19. The display device of claim 18, wherein
the red color filter is disposed in the red light-emitting area and the non-light-emitting area, and
the red color filter disposed in the non-light-emitting area forms a red dummy color filter.

20. The display device of claim 19, wherein
the green color filter is disposed in the green light-emitting area and the non-light-emitting area, and
the green color filter disposed in the non-light-emitting area forms a green dummy color filter.

21. The display device of claim 20, wherein the blue dummy color filter, the red dummy color filter, and the green dummy color filter overlap in the first direction in the non-light-emitting area.

22. The display device of claim 21, wherein the blue dummy color filter is disposed closer to the second substrate than the red dummy color filter or the green dummy color filter.

23. The display device of claim 16, further comprising:
a low refractive layer disposed on the red color filter, the green color filter, and the blue color filter, wherein
a refractive index of the low refractive layer is less than or equal to about 1.2.

24. The display device of claim 23, further comprising:
a first insulating layer disposed on the low refractive layer, wherein
a refractive index of the first insulating layer is in a range of about 1.4 to about 1.6.

25. The display device of claim 24, wherein the first insulating layer includes silicon oxide.

26. The display device of claim 1, further comprising:
a buffer layer disposed between the display panel and the color converting panel, wherein
a refractive index of the buffer layer is in a range of about 1.6 to about 1.7.

27. The display device of claim 26, further comprising:
a second insulating layer disposed between the color converting layer and the buffer layer, and between the transmissive layer and the buffer layer, wherein
a refractive index of the second insulating layer is in a range of about 1.4 to about 1.6.

28. The display device of claim 27, wherein the second insulating layer includes SiON.
